(19) United States
(12) Patent Application Publication
(10) Pub. No.: US 2003/0163773 A1
(43) Pub. Date: Aug. 28, 2003

(54) Multi-core controller

(76) Inventors: James J. O'Brien, Hull, MA (US); Jean Claude Coutant, Quincy, MA (US)

Correspondence Address: Sampson & Associates, P.C., 50 Congress Street, Boston, MA, 02109, US

(21) Appl. No.: 10/083,224

(22) Filed: Feb. 26, 2002

(51) Int. Cl. G01R 31/28

(52) U.S. Cl. 714/726

(57) ABSTRACT

Embodiments of the present invention include a multi-core controller for use with an emulator to enable devices on a multiple device JTAG scan chain to be individually controlled for emulation/debugging operations. Non-JTAG instructions may be used in combination with JTAG compliant instructions to control individual devices in the JTAG scan chain.

### BACKGROUND

Since the mid-1970s, the structural testing of loaded printed circuit boards (PCBs) has relied very heavily on the use of the so-called in-circuit “bed-of-nails” technique. This method of testing makes use of a fixture containing a bed-of-nails to access individual devices on the board through test lands laid into the copper interconnect, or other convenient contact points. Testing then generally proceeds in two phases: power-off tests followed by power-on tests.

Power-off tests check the integrity of the physical contact between nail and the on-board access point. They then may carry out open and shorts tests based on impedance measurements. Power-on tests apply stimulus to a chosen device on a board, with an accompanying measurement of the response from that device. Other devices that are electrically connected to the device-under-test are usually placed into a safe state (a process called “guarding”). In this way, the tester is able to check the presence, orientation, and bonding of the device-under-test in place on the board.

Fundamentally, the in-circuit bed-of-nails technique relies on physical access to all devices on a board. For plated-through-hole technology, the access is usually gained by adding test lands into the interconnects on the “B” side of the board—that is, the solder side of the board. The advent of surface mount devices meant that manufacturers began to place components on both sides of the board—the “A” side and the “B” side. The smaller pitch between the leads of surface-mount components caused a corresponding decrease in the physical distance between the interconnects. This had serious impact on the ability to place a nail accurately onto a target test land. The question of access was further compounded by the development of multi-layer boards.

In the 1980s a group known as the Joint Test Action Group (JTAG) examined the problem and its possible solutions. Their preferred method of solution was based on the concept of placing a series of cells forming a serial shift register, around the boundary of the device. This shift register became known as a boundary-scan register. The JTAG approach ultimately became an international standard known as the IEEE 1149.1 “Test Access Port and Boundary-Scan Architecture”. As used herein, the terms “JTAG”, “JTAG compliant”, and/or “IEEE 1149.1” are interchangeably used to refer to this standard (including subsequent revisions and modifications thereof) and/or devices that are compliant with this standard.

The boundary-scan cells forming the boundary-scan register essentially formed a series of “virtual nails”, which may be used in a manner similar to the actual nails discussed above to test the presence, orientation, and bonding of devices in place on a board. In particular, the prime function of the bed-of-nails in-circuit tester, and thus, the boundary-scan architecture, has been to test for manufacturing defects, such as missing devices, damaged devices, open and short circuits, misaligned devices, and wrong devices.

It was assumed that devices had already been tested for functionality when they existed only as devices (i. e., prior to assembly on the board). Boundary-scan architecture was viewed as an alternative way of testing for the presence of manufacturing defects, including defects caused by shock, such as electrical shock (e. g., electrostatic discharge), mechanical shock (e. g., clumsy handling), or thermal shock (e. g., hot spots caused by the solder operation). A defect, if it occurs, is likely present either in the periphery of the device (leg, bond wire, driver amplifier), in the solder, or in the interconnect between devices. It is very unusual to find damage to the core logic without there being some associated damage to the periphery of the device. In-circuit testers thus generally were not configured or intended to prove the overall functionality of the devices.

However, with the proliferation of complex board mounted systems, it is often desirable to effect in-depth testing of individual components. A need thus exists for a method and apparatus for emulating and/or debugging individual devices using existing scan chain architecture.

### SUMMARY

According to an embodiment of this invention, a method is provided, which includes placing a memory structure in a path of a JTAG scan chain in response to an instruction, the memory structure having multiple locations, at least portions of the memory structure being capable of storing first data and second data. The method also includes serially receiving at least one signal containing first data via the JTAG scan chain, storing the first data in the memory structure, receiving at least one other signal from at least one component on the JTAG scan chain, transmitting the other signal to at least one other component on the scan chain, placing second data into the memory structure, and serially transmitting the second data via the JTAG scan chain.

Another embodiment of the invention includes a controller for controlling multiple components. The controller includes an instruction memory structure, a data memory structure, and control logic coupled to the instruction memory structure and the data memory structure. Signal logic is coupled to the data memory structure, and a JTAG-compliant TAP controller is coupled to the instruction memory structure. Serial input and output ports are provided, at least one of the serial input port and the serial output port being selectively couplable to at least one of the instruction memory structure and the data memory structure. A plurality of parallel inputs are coupled to the signal logic and are available to receive signals from each of the multiple components. A plurality of parallel outputs are coupled to the signal logic and available to transmit signals to each of the multiple components. The control logic is configured to couple the data memory structure to the serial input port and serial output port upon implementation of an instruction in the instruction memory structure. The signal logic is configured to receive and transmit signals between the multiple components upon receipt via the serial input port of first data in a first location of the data memory structure. The signal logic is also configured to place second data into a second location of the data memory structure in response to the first data, and the data memory structure is configured to serially transmit the first and second data via the serial output port.

In a further aspect of the invention, a method includes transmitting a first instruction to place multiple instruction memory structures on a JTAG scan chain, and serially transmitting a second instruction via the JTAG scan chain, the second instruction to place a controller data memory structure on the JTAG scan chain. The method further includes serially transmitting at least one signal containing first controller data via the JTAG scan chain, transmitting at least one other signal to a component on the JTAG scan chain, and serially receiving second controller data corresponding to multiple devices from the data memory structure via the JTAG scan chain.

In still another aspect of the invention, an emulator is provided for debugging multiple devices on a JTAG scan chain. The emulator includes a processor, a scan chain signal handler configured to transmit and receive signals via the scan chain, a TAP controller signal handler configured to send and receive instructions via parallel connections to each TAP controller on the scan chain, and a non-JTAG signal handler configured to transfer non-JTAG signals to and from a controller disposed on the scan chain.

In another aspect, a method includes, with an emulator, transmitting a first instruction to place multiple instruction memory structures on a JTAG scan chain, the scan chain including a plurality of devices and a controller, and also with the emulator, serially transmitting a second instruction via the JTAG scan chain. The method also includes placing a memory structure of the controller in a path of the JTAG scan chain in response to the second instruction, the memory structure having multiple locations, at least portions of the memory structure being capable of storing first data and second data. Further aspects of this method include, with the emulator, serially transmitting at least one signal containing first controller data via the JTAG scan chain, serially receiving the one signal with the controller, storing the first data in the memory structure, transmitting at least one other signal from the emulator, receiving the other signal with the controller, transmitting the other signal from the controller to the plurality of devices, using the controller to place second data into the memory structure, serially transmitting the second data corresponding to the devices via the JTAG scan chain, and serially receiving the second data with the emulator via the JTAG scan chain.

A yet further aspect of the invention includes a system including a JTAG scan chain having multiple devices, and an emulator for debugging the multiple devices. The emulator includes a processor, a scan chain signal handler coupled to the scan chain to transmit and receive signals, a TAP controller signal handler configured to send and receive instructions via parallel connections to each TAP controller on the scan chain, and a non-JTAG signal handler configured to transfer non-JTAG signals to and from a controller disposed on the scan chain. The system also includes a controller having an instruction memory structure, a data memory structure, control logic coupled to the instruction memory structure and the data memory structure, signal logic coupled to the data memory structure, and a JTAG-compliant TAP controller coupled to the instruction memory structure. A serial input port is coupled to the scan chain signal handler, a serial output port is coupled to the scan chain, and at least one of the serial input port and the serial output port are selectively couplable to at least one of the instruction memory structure and the data memory structure. A plurality of parallel inputs are coupled to the signal logic and to each of the multiple components and to the non-JTAG signal handler. A plurality of parallel outputs are coupled to the signal logic and to each of the multiple components and to the non-JTAG signal handler. The control logic is configured to couple the data memory structure to the serial input port and serial output port upon implementation of an instruction in the instruction memory structure received from the emulator. The signal logic is configured to receive and transmit signals between the multiple components upon receipt via the serial input port of first data in a first location of the data memory structure. The signal logic is configured to place second data into a second location of the data memory structure in response to the first data, and the data memory structure is configured to serially transmit the first and second data via the serial output port to the emulator.

### BRIEF DESCRIPTION OF THE DRAWINGS

The above and other features and advantages of this invention will be more readily apparent from a reading of the following detailed description of various aspects of the invention taken in conjunction with the accompanying drawings, in which:

FIGS. 1 to 5 are schematic representations of various aspects of boundary scan architecture of the prior art;

FIG. 6 is a schematic representation of a multi-core controller (MCC) of the present invention;

FIG. 7A is a schematic representation of an emulator in accordance with aspects of the present invention;

FIG. 7B is a schematic representation of a JTAG boundary scan chain incorporating the MCC of FIG. 6;

FIGS. 8A and 8B are schematic representations of exemplary steps used to place an MCC on a JTAG boundary scan chain;

FIG. 9 is a schematic block diagram, on an enlarged scale, of a portion of the MCC of FIG. 6;

FIG. 10 is a schematic representation of a boundary scan chain of the prior art; and

FIG. 11 is a view similar to that of FIG. 10, of a boundary scan chain incorporating an embodiment of the present invention.

### DETAILED DESCRIPTION

Referring to the figures set forth in the accompanying drawings, illustrative embodiments of the present invention will be described in detail hereinbelow. For clarity of exposition, like features shown in the accompanying drawings shall be indicated with like reference numerals and similar features as shown in alternate embodiments in the drawings will be indicated with similar reference numerals.

Embodiments of the present invention include a multi-core controller which may be used with an emulator, to enable devices on a multiple device JTAG scan chain to be individually controlled using non-JTAG control signals, such as for emulation/debugging operations. The invention advantageously enables a single non-JTAG control signal to be transmitted to multiple devices, and enables multiple non-JTAG control signals to be fed back to a single component on the scan chain. Alternate embodiments of this invention further enable the use of multiple JTAG TAP controllers within a single device, while maintaining JTAG compliance for instructions such as BYPASS and IDCODE commands.

Particular embodiments of the present invention enable non-JTAG instructions to be used in combination with JTAG compliant instructions to control individual devices in the JTAG scan chain. Examples of JTAG enabled (also referred to herein as JTAG compliant) devices that may be used in conjunction with embodiments of the present invention include the 6xx ,7xx and 82xx family of processors available from Motorola® (Palatine, Ill.), as well as POWERPC® (International Business Machines Corporation ‘IBM’, Armonk, N.Y.), 4xx (IBM), MIPS® (Mips Technologies, Inc., Mountain View Calif.), and ARM (Arm Limited, Cambridge, England) processors.

Alternate embodiments of the present invention may be used with other types of devices, such as IEEE 1149.1 compatible devices capable of in-circuit PAL, FLASH and FPGA programming. These alternative embodiments may provide features such as boundary scan signal display and in-circuit testing.

Where used in this disclosure, the term “emulator” is used in a manner familiar to those skilled in the art, namely, to refer to hardware and/or software configured to enable a host processor to run software designed for a target processor, and which may include a source-level debugger. For example, “emulator” may include the visionICE™ real-time in-circuit emulator, and/or visionPROBE™ hardware-assisted debugging & test tool products available from Wind River Systems, Inc. (Alameda, Calif.) alone or in combination. These products typically include a translation module, e.g., a Field Programmable Gate Array or the like, configured to translate emulation/debugging instructions into a format, such as JTAG, which is usable by the target device(s). Such an emulator is referred to herein as “emulator 110”.

Referring now to Figures, the apparatus of the present invention will be more thoroughly described. Prior to discussing the configuration and function of embodiments of this invention, a brief discussion of JTAG boundary-scan architecture and operation is in order.

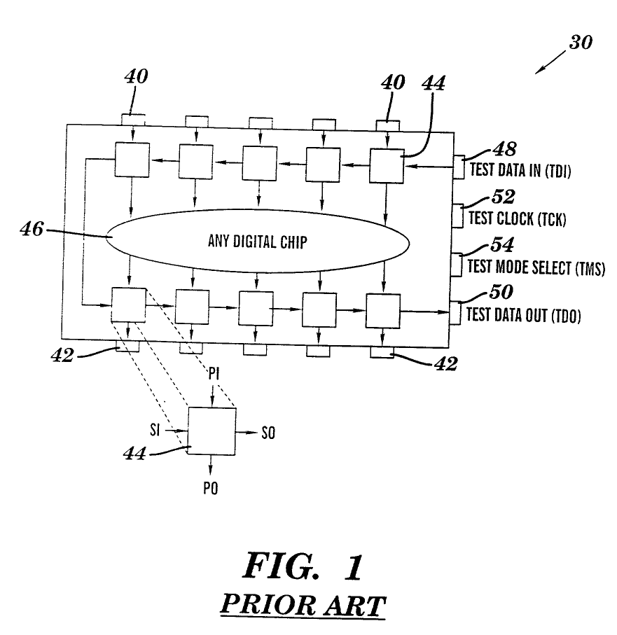

Turning to FIG. 1, in a JTAG compliant device (processor) 30, each primary input 40 and primary output 42 signal is supplemented with a multi-purpose memory element known as a boundary-scan cell 44. Cells 44 coupled directly to primary inputs 40 are generally referred to as “input cells.” Similarly, cells 44 coupled directly to primary outputs 42 are referred to as “output cells.” As used herein, when distinguishing between elements within a device, the terms “input” and “output” are defined relative to the core logic 46 of the device. The terms “input” and “output” may also be used herein to reference particular interconnects between two or more devices. As also used herein, the term “component” when used in reference to a scan chain, refers to substantially anything coupled to a scan chain, including devices 30, 30′, 30″, MCC 108, JTAG connector 109, and/or emulator 110. The term “device” as used herein refers to any such component having its own processor and/or TAP controller, including devices 30, 30′, 30″, and MCC 108.

The collection of boundary-scan cells 44 is configured as a parallel-in, parallel-out shift register. A parallel load operation, referred to as a “capture” operation, causes signal values on device input pins 40 to be loaded into the input cells and, signal values passing from the core logic 46 to device output pins 42 to be loaded into the output cells. A parallel unload operation—called an “update” operation—causes signal values already present in the output scan cells to be passed out through the device output pins 42. Signal values already present in the input scan cells will be passed into the core logic 46.

Data may also be shifted around the shift register, in serial mode, starting from a dedicated device input pin referred to as “Test Data In” (TDI) pin 48 and terminating at a dedicated device output pin referred to as “Test Data Out” (TDO) pin 50. A test clock, TCK, is fed into clock pin 52 and the mode of operation is controlled by a dedicated “Test Mode Select” (TMS) pin 54.

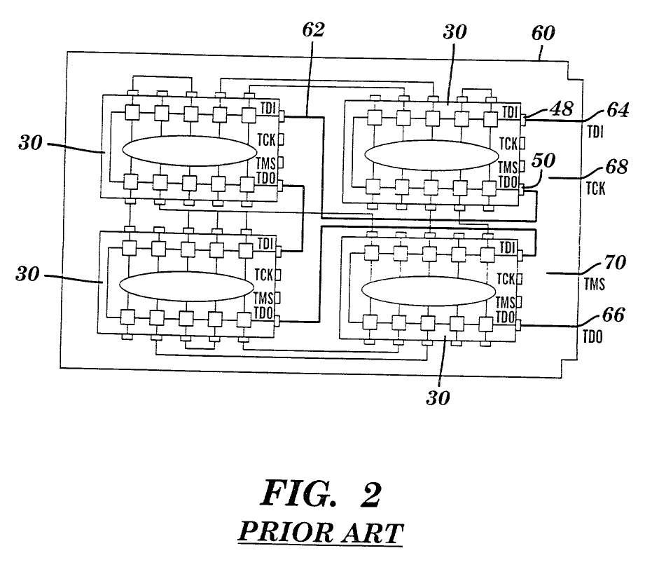

At the device level, the boundary-scan elements 44 generally do not contribute to the functionality of the core logic 46. Rather, the boundary-scan path (or chain) 62 (FIG. 2) is independent of the function of the device 30. The benefit of the scan path 62 is at the board level as shown in FIG. 2.

Turning now to FIG. 2, an exemplary board 60 contains four boundary-scan devices 30. The board 60 includes an edge-connector TDI input 64 connected to the TDI 48 of the first device. TDO 50 of the first device is connected to TDI 48 of the second device, and so on, creating a global scan path 62 terminating at an edge connector TDO output 66. TCK input 68 is connected in parallel (not shown) to each device TCK 52. TMS 70 is similarly connected in parallel (not shown) to each TMS 54.

Particular tests may be applied to the device interconnects via the global scan path 62—by loading the stimulus values into the appropriate device-output scan cells 44, by the process of entering a value into the edge connector TDI input 64 (i.e., using a “shift-in” operation), applying the stimulus (“update” operation), capturing the responses at device-output scan cells (“capture” operation), and shifting the response values out to the edge connector TDO (shift-out operation).

Using the boundary-scan cells to test the core functionality is called “internal test,” shortened to Intest. Using the boundary-scan cells to test the interconnect structure between two devices is called “external test,” shortened to Extest. The use of the cells for Extest is the major application of boundary-scan architecture, searching for opens and shorts plus damage to the periphery of the device. Intest has only typically been used for very limited testing of the core functionality (i. e., an existence test, to identify defects such as devices missing, incorrectly oriented, or misalignment.

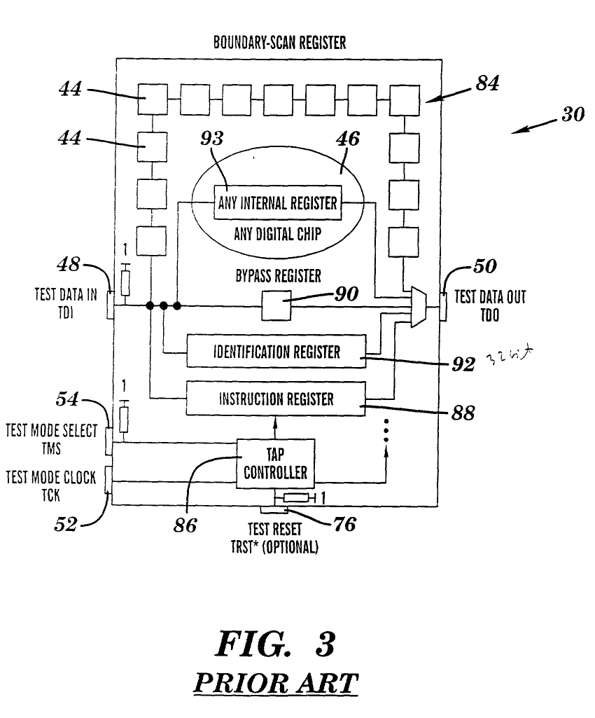

Turning now to FIG. 3, the JTAG architecture is shown in greater detail. As shown, device 30 includes Test Data In (TDI) 48, Test Mode Select (TMS) 54, Test Clock input (TCK) 52, Test Data Out (TDO) 50—and an optional test pin Test Reset (TRST) 76. These pins are collectively referred to as the Test Access Port (TAP).

Boundary-scan cells 44 directly coupled to each device primary input and primary output pin (not shown), are interconnected internally to form a serial boundary-scan register (Boundary Scan) 84.

Additional features include a finite-state machine TAP controller 86 having TCK 52, TMS 54, and optionally, TRST 76, inputs. An n-bit Instruction Register (IR) 88 is provided to hold a current instruction. A 1-bit bypass register (Bypass) 90 is provided, and optionally, a 32-bit Identification Register (Ident) 92, capable of being loaded with a permanent device identification code, may also be included.

At any time, only one of the registers (e.g., 84, 88, 90, 92, or a register 93 within core 46) may be connected from TDI 48 to TDO 50. The selected register is identified by the decoded output of the IR. Certain instructions are mandatory, such as Extest (boundary-scan register selected), whereas others are optional, such as the Idcode instruction (Ident register selected).

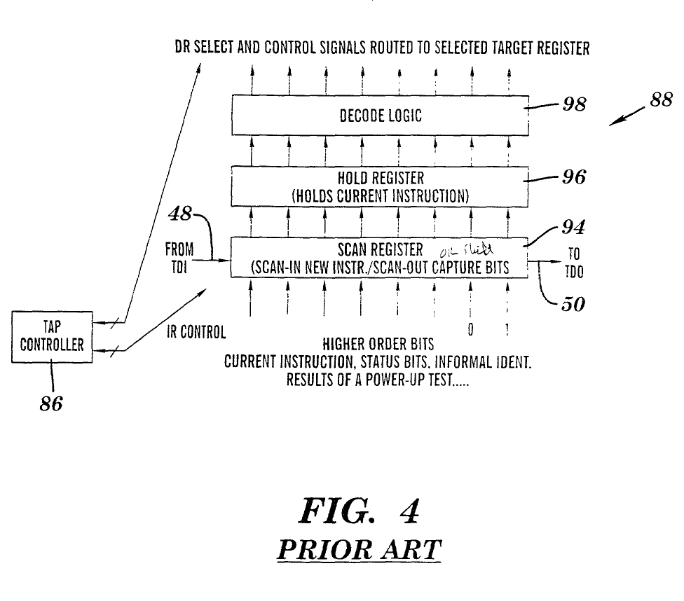

Turning now to FIG. 4, Instruction Register (IR) 88 includes a shift section (also referred to as a scan register) 94 that may be connected to TDI 48 and TDO 50, and a hold section 96, that holds a current instruction.

Typically, some decoding logic 98 may be associated with the two sections 94 and 96 depending on the width of the register and number of different instructions associated with the particular device 30. Control signals to the IR 88 originate from TAP controller 86 and either cause a shift-in, shift-out through the IR shift section 94, or cause the contents of the shift section 94 to be passed to the hold section 96 (i.e., an update operation). It is also possible to load (capture) certain known (e.g., “hard-wired”) values into the shift section 94.

The IEEE 1149.1 Standard describes three instructions: Bypass, Sample/Preload, and Extest. The Bypass instruction is assigned an all-1s code and when executed, causes the Bypass register 90 (FIG. 3) to be placed between the TDI 48 and TDO 50 pins. By definition, the initialized state of the hold section 96 of IR 88 should contain the Bypass instruction unless the optional Identification Register (Ident) 92 has been implemented, in which case, the Idcode instruction is present in hold section 96.

The Sample/Preload instruction selects the boundary-scan register 84 when executed. This instruction sets up the boundary-scan cells 44 either to sample (capture) values moving in to the device 30 or to preload known (e.g., “hard wired”) values into the output boundary-scan cells 44 prior to some follow-on operation.

The Extest instruction selects the boundary-scan register 84 when executed, preparatory to interconnect testing. The code for Extest is defined as the all-0s code.

The IEEE 1149.1 Standard also defines a number of optional instructions. Examples of optional instructions include: Intest, the instruction that selects the boundary-scan register 84 preparatory to applying tests to the core logic of the device; and Idcode, the instruction to select the Identification Register 92, preparatory to loading the Idcode code and reading it out through TDO 50.

Additional instructions include Clamp, which drives preset values onto the outputs of devices 30 (values which were established previously using the Sample/Preload instruction) and then selects the Bypass register 90 between TDI 48 and TDO 50 (unlike the Sample/Preload instruction). Clamp may be used to set up safe “guarding” values on the outputs of certain devices, for example, to avoid bus contention problems. Highz is similar to Clamp, but leaves the device output pins in a high-impedance state. Highz also selects the Bypass register 90 between TDI 48 and TDO 50.

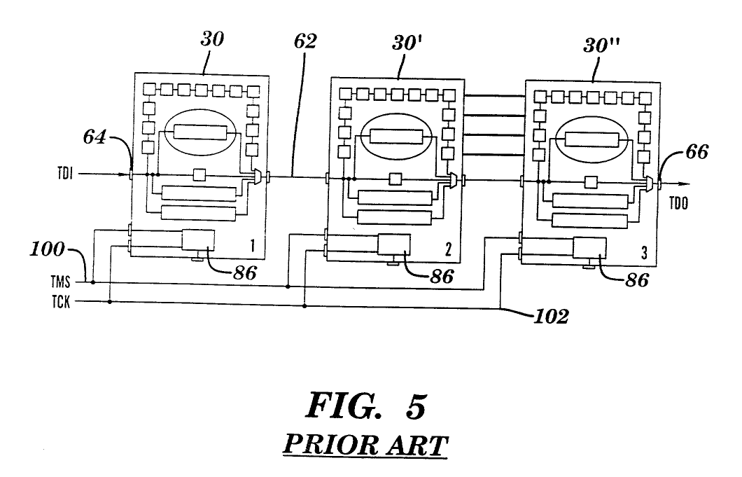

Turning now to FIG. 5, IR 88 (FIG. 3) loads and decodes its contents as follows. For example, one may wish to place device 30 (the first device in the chain) into bypass mode (to shorten the time it takes to get test stimulus to follow-on devices 30′ and 30″) and place devices 30′ and 30″ into Extest mode preparatory to setting up tests to check the interconnect between devices 30′ and 30″. This example requires loading the Bypass instruction (all-1s) into the IR 88 of device 30, and the Extest instruction (all-0s) into the IRs 88 of devices 30′ and 30″.

Step 1 in this example is to connect the IRs 88 (FIG. 3) of all three devices between their respective TDI 48 and TDO 50 pins. This is achieved by placing a predetermined sequence of values on the TMS control line 100 that is coupled in parallel to the TAP controller 86 of each device 30, 30′, 30″. (As shown, both the TMS line 100 and TCK line 102 are connected to all devices in parallel.) Any sequence of values on TMS line 100 will be interpreted in the same way by each TAP controller 86.

Step 2 is to load the appropriate instructions into the various IRs 88 through scan path 62 that now serially connects them to one another. In the event each IR 88 simply contains two-bits, this operation amounts to a serial load of the sequence 110000 into the edge-connector TDI 64 to place 00 in IR 88 of each device 30′ and 30″, and place 11 in IR 88 of device 30. The IRs 88 are now set up with the correct instructions loaded into their shift sections 94.

In step 3, values are placed on TMS line 100 to cause each TAP controller 86 to issue control-signal values that transfer the values in the shift sections 94 of the IRs 88 to hold sections 96 where they become the “current” instruction. This is the Update operation. At this point, the various instructions are obeyed—that is, device 30 deselects its IR 88 and selects its Bypass register 90 between its TDI 48 and TDO 50 (i.e., to execute its Bypass instruction). Devices 30′ and 30″ deselect their IRs 88 and select their boundary-scan registers 84 between their TDI 48 and TDO 50 (i.e., to execute their Extest instructions). The devices 30, 30′, and 30″ are now set up for the Extest operation.

Additional discussion of the IEEE 1149.1 specification, and scan chain communication in general, is set forth in commonly owned U.S. patent application Ser. No. 09/921,250, entitled MULTIPLE DEVICE SCAN CHAIN EMULATION/DEBUGGING, filed on Aug. 2, 2001, which is fully incorporated by reference herein.

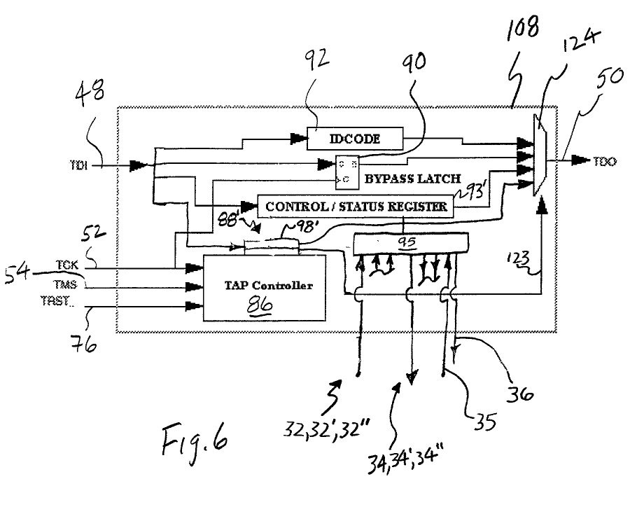

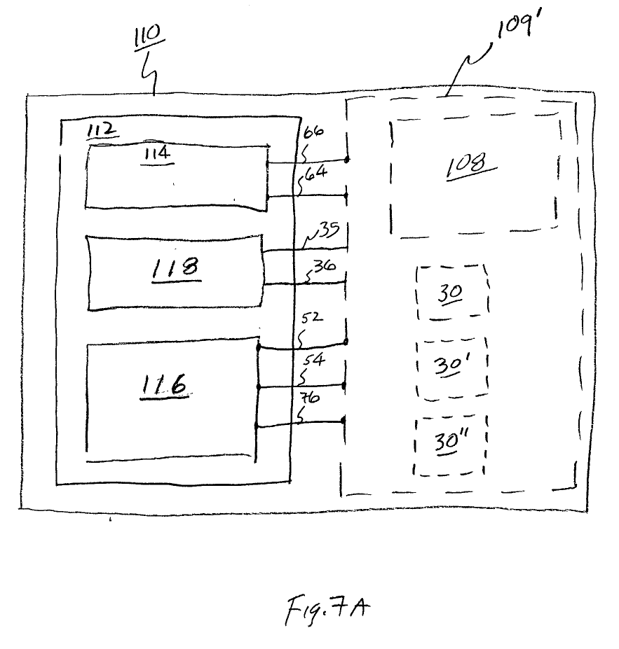

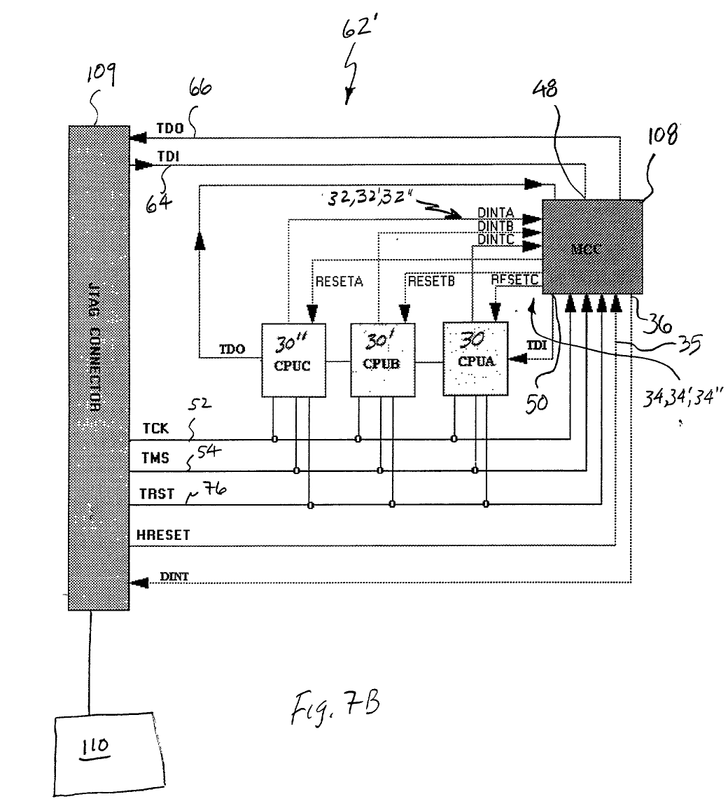

Referring now to FIGS. 6-12, embodiments of the present invention will be described in detail. As shown in FIGS. 6 and 7, an embodiment of the present invention includes a multi-core controller (MCC) 108 disposed within a scan chain 62′ to control multiple processors 30, 30′, etc., within the chain. The MCC 108 is used to control nominally all the non-JTAG signals used for multiple processor control. As mentioned hereinabove, this embodiment may be used with substantially any JTAG/IEEE 1149.1 compliant devices. Advantageously, embodiments of the present invention may use essentially the same approach to control both internal (e.g., embedded) processors disposed within a single device, and external processors. The MCC 108 thus serves as an interface used to control these multiple processors. The MCC 108 maybe used to transmit multiple non-JTAG signals of the same characteristic to a single source, or a single control signal to multiple destinations 30, 30′, etc. For example, MCC 108 may be used to control the reset signals to more than one CPU 30, 30′, or to have one CPU 30 interrupt another CPU 30′. Added support may be added to enable software applications access to this component via a parallel memory mapped interface (not shown), such as to enable various diagnostic software applications to access the status and control registers.

Turning to FIG. 6 in particular, MCC 108 includes an IEEE 1149.1 compliant TAP controller 86, with TCK 52, TMS 54, and TRST 76 inputs. MCC also includes a TDI 48 and a TDO 50. A Bypass Register (e.g., latch) 90, an Identification Register 92, a Data register 93′, and an Instruction Register 88′ are also provided, and are selectively connectable between the TDI 48 and TDO 50. Control signals to the IR 88′ originate from TAP controller 86. At any time, only one of the registers (e.g., 84, 88, 90, 92, or a register 93′ within core 46) may be connected from TDI 48 to TDO 50. The selected register is identified by the output of the IR 88′ as decoded by a decoder (also referred to as control logic) 98′, and is placed between TDI 48 and TDO 50 by signals transmitted via connection 123 to MUX 124. MCC 108 also includes a signal logic module (signal logic) 95 coupled to register 93′. Signal logic 95 includes a plurality of non-JTAG input/output ports 32/34, 32′/34′, and 32″/34″, for respectively coupling the MCC to each device 30, 30′, and 30″. Another pair of non-JTAG input and output ports 35 & 36 are configured for coupling signal logic 95 directly to a JTAG connector 109 (FIG. 7B). These non-JTAG ports are discussed in greater detail hereinbelow with respect to FIG. 7B. Registers in MCC 108 may be implemented using available memory structures, such as dedicated registers, SRAM, embedded DRAM, etc.

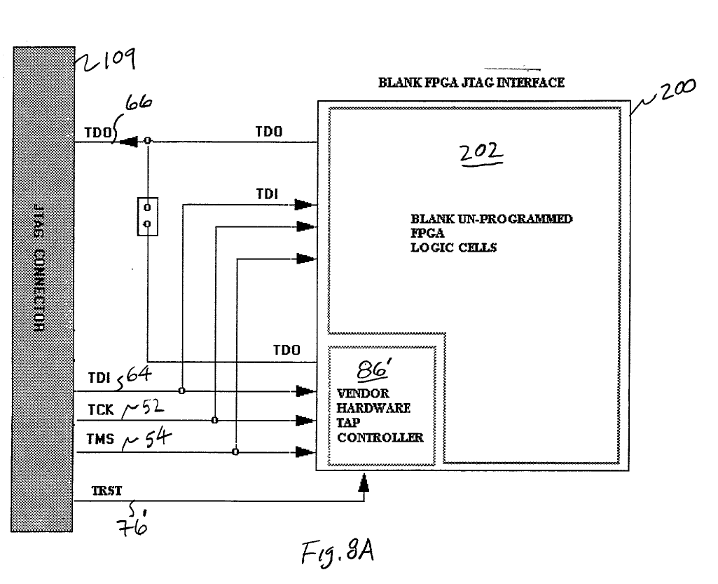

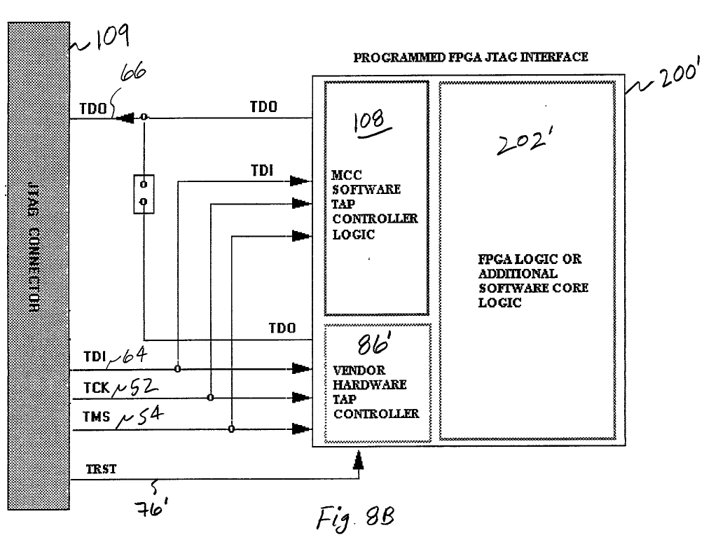

Turning now to FIG. 7A, emulator 110 includes a processor 112, which further includes a scan chain signal handler 114 configured to send and receive JTAG signals and data via a JTAG scan chain. The emulator also includes a TAP controller signal handler 116 configured to send and receive instructions via parallel connections to each TAP controller in the scan chain. A non-JTAG signal handler 118 transfers non-JTAG signals to and from MCC 108, via input and output ports 35 and 36. Optionally, as mentioned above, emulator 110 may include a JTAG connector 109′ (shown in phantom), which may in turn, optionally include MCC 108 and devices 30, 30′, 30″ (also shown in phantom). The emulator includes various ports, including TDI 64, TDO 66, TCK 52, TMS 54, and TRST 76. Exemplary interconnections between JTAG connector 109, MCC 108, and devices 30, 30′, 30″, will be shown and described in greater detail hereinbelow, with respect to FIGS. 7B, 8A, and 8B.

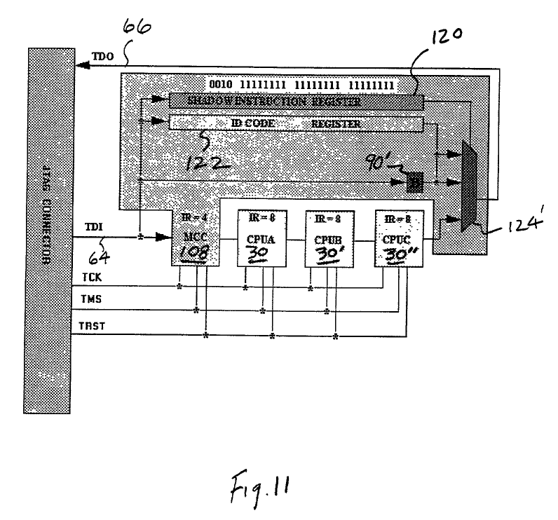

Turning to FIG. 7B, MCC 108 is disposed as the first device on serial scan chain 62′. It may also be considered to be the last device on the chain since it sends TDO data back to the JTAG connector through edge connector TDO 66. (See, for example, FIG. 11, which schematically illustrates this first and last positioning.) Other devices (30, 30′, 30″) on the scan chain 62′ may be in any order. Exemplary embodiments shown and described herein support up to 4 processors. However, in light of the present disclosure, the skilled artisan will recognize that additional components may be supported by using additional MCCs 108, or by simply expanding the characteristics set forth herein.

Moreover, although for clarity and convenience, MCC 108 is shown and described in FIG. 7B as a discrete device, the skilled artisan will recognize that the MCC may be embedded or otherwise incorporated into one or more other devices in scan chain 62′. For example, MCC 108 may be incorporated into JTAG connector 109 and/or emulator 110, such as shown in FIG. 7B, or may be integrally disposed with other devices 30, etc., such as within a single FPGA 200 shown and described hereinbelow with respect to FIGS. 8A and 8B.

In the example shown in FIG. 7B, 3 CPUs 30, 30′, and 30″ are coupled to an MCC 108 in a scan chain 62′ through a JTAG connector 109 connected to a discrete emulator/debugger 110. The 3 CPUs 30, 30′, 30″ and the MCC 108, are each coupled in parallel to the TCK, TMS, TRST, and HRESET ports of JTAG connector 109, in a manner that is conventional for IEEE 1149 scan chains. As also shown, the scan chain 62′ extends from the edge connector TDI input 64 (coupled directly to the JTAG connector 109), to TDI 48 of the MCC, to TDO 50 of MCC 108, and then extends serially to each of the CPUs 30, 30′, and 30″. The chain then extends from the TDO of device 30″ back to MCC 108, which in turn, terminates the chain 62′ at edge connector TDO 66 which is coupled directly to JTAG connector 109.

In addition to the foregoing JTAG scan chain connections, as mentioned hereinabove, each device 30, 30′, and 30″ has an additional input/output pair connected directly (i.e., in parallel) to the MCC 108 (i.e., to signal logic 95) at respective sets of non-JTAG input/output ports 32/34, 32′/34′, and 32″/34″, respectively. MCC 108 also includes another pair of non-JTAG input and output ports 35 & 36 configured for coupling directly to JTAG connector 109. These parallel connections between the MCC and each device, in combination with ports 35 & 36, may advantageously be used to facilitate non-JTAG (i.e., non-scan chain) communication to and from JTAG connector 109 (and module 118 of emulator 110 shown in FIG. 7A).

Examples of non-JTAG communication facilitated by this embodiment include MCC 108 receiving a single reset signal from JTAG connector 109 (e.g., originating from module 118 (FIG. 7A) of emulator 110), via port 35, which is then passed to each processor 30, 30′, and 30″ through output ports 34, 34′, and 34″. Similarly, MCC 108 may receive interrupt signals from each CPU, through input ports 32, 32′, and 32″, which may then be passed back to the JTAG connector 109 using a single interrupt signal transmitted through port 36.

Although the devices 30, 30′, 30″ may each be hardware devices, one or more of them may optionally be implemented as software, i.e., as conventional ‘soft core’ devices loaded into a computer readable medium. For example, such soft core devices may be loaded into memory (e.g., FPGA 200 or FIGS. 8A and 8B) associated with MCC 108, through the scan chain 62′. An exemplary method for loading MCC 108, and optionally, soft core devices 30, etc., is shown in FIGS. 8A and 8B.

Turning to FIG. 8A, a blank (i.e., unprogrammed/uninitialized) FPGA 200 typically includes a hardware TAP controller 86′, and blank logic cells 202. TAP controller 86′ includes a TRST 76′ input, and both controller 86′ and cells 202 include parallel TCK 52, TMS 54, and TDI 64 inputs, and TDO 66 outputs.

Once the FPGA 200 is connected to JTAG connector 109 as shown, and powered up, the TAP controller 86′ may be used to download logic from the emulator through JTAG connector 109, to effect MCC 108. Turning now to FIG. 8B, the device loaded with MCC 108 is shown as FPGA 200′. Since the MCC 108, including its own TAP controller 86 (FIG. 6) is now available, the hardware TAP controller 86′ is no longer needed. At this point, the TRST 76′ is asserted by the emulator 110 (FIG. 7B) to keep the TAP controller 86′ inactive. At this point, FPGA 202′ may be connected to external devices 30, 30′, etc., to form scan chain 62′. Alternatively, one or more ‘soft core’ devices 30, 30′, etc., may be loaded into remaining logic cells 202′, so that two or more of the processors of scan chain 62′ are disposed within a single chip as mentioned hereinabove.

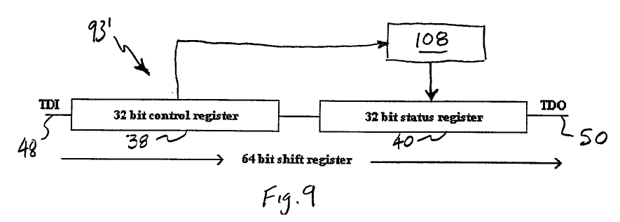

The foregoing functionality of MCC 108 is facilitated by use of IR 88, data register 93′, and signal logic 95, which will now be described in greater detail. As mentioned hereinabove, the IR 88 (and register 93′), is selected by TAP controller 86. In the particular embodiment shown, the instruction register 88 is 4 bits long, and the data register 93′ is 64 bits long. As best shown in FIG. 9, the 64-bit data register 93′ includes two 32-bit registers, i.e., a 32 bit control register 38, and a 32 bit status register 40. The control register 38 effectively serves as the MCC's read register, while the status register 40 serves as the MCC's write register. All data shifted into the MCC 108 will be 32 bits in length and arrive at control register 38 through TDI 48. All data shifted out of the MCC will exit from the status register 40 through TDO 50, and will similarly be 32 bits in length. For every 32-bits shifted into the control register, 32-bits will be shifted out of the status register. In particular embodiments, data shifted into and out of data register 93′ will be LSB (Least Significant Bit) first.

Initially, the data register 93′ is selected by an instruction (MCC Select, discussed below with respect to Table 1) fed to instruction register 88. Once selected, data is then serially fed via the scan chain to the control portion (location) of data register 93′. Examples of such data are shown in Table 2 below. Once desired data (associated with a particular operation) has been received by register 93′, desired signal(s) associated with the operation may be received at signal logic module 95 from one or more of the components (e.g., devices 30, 30′, 30″ or connector 109), and re-transmitted to others of the components. Signal logic module 95 will then place associated status data into the status portion of register 93′.

For example, once HRESET ENABLE TO PROCESSOR data has been received in the control portion of register 93′, an HRESET signal may be received via input port 35, and subsequently driven out to devices 30, 30′, and 30″. Signal logic 95 will then write status data into the status portion of register 93′, as shown in Table 3. The contents of register 93′ may then be serially transmitted via output ports 50 and 66 to emulator 110.

In the embodiment shown, the Instruction Register 88 is 4-bits in length to provide up to 16 possible instructions or commands shown in Table 1 below. As also discussed hereinabove, the mandatory instructions required for IEEE 1149 compliancy are EXTEST, SAMPLE/PRELOAD and BYPASS. The other 13 instructions are user definable. The present invention defines one of these user definable instructions as “MCC Select”, to place the data register 93′ on the scan chain 62′ (i.e., between the MCC's TDI 48 and TDO 50). Similarly, the “IDCODE” instruction places the Identification Register 92 (FIG. 3) on the scan chain 62′. The remaining instructions, labeled as USER, are available for future use.

TABLE 1

| | | |
|---|---|---|
| EXTEST | (0000) | Jtag Standard command. |
| SAMPLE | (0001) | Jtag Standard command. |
| IDCODE | (0010) | User Definable IDCODE |
| | | register. |
| USER | (0011) | User definable |
| USER | (0100) | User Definable |
| MCC Select | (0101) | Place Register 93′ of |
| | | the MCC between TDI and |
| | | TDO. |
| USER | (0110) | User Definable |
| USER | (0111) | User Definable |
| USER | (1000) | User Definable |
| USER | (1001) | User Definable |
| USER | (1010) | User Definable |
| USER | (1011) | User Definable |
| USER | (1100) | User Definable |
| USER | (1101) | User Definable |
| USER | (1110) | User Definable |
| BYPASS | (1111) | Jtag Standard command. |

The formats of control register 38 and status register 40 are shown in the following Tables 2 & 3. As mentioned hereinabove, embodiments of the present invention shown and described herein, including the register formats of Tables 2 & 3, provide control for 3 CPU's 30, 30′, and 30″, using the MCC component. The skilled artisan may, however, implement variations of this design that accommodate additional CPUs, as mentioned above. The following 32-bit control and status register formats and bit definitions correspond to a 32-bit register.

TABLE 2
Control Register Format

0-3, HRESET ENABLE TO PROCESSOR 1 through 3.
Bit positions 0-3 when SET will enable the hardware reset signal from the
jtag port 109 to be driven out to each processor. Clearing each bit will
disable the signal.
4-7, TRST ENABLE TO PROCESSOR 1 through 3.
Bit positions 4-7 when SET will enable the test reset signal from the jtag
port 109 to be driven out to each processor.
8-11, DINT ENABLE FROM PROCESSOR 1 through 3,
TO CONNECTOR
Bit positions 8-11 when SET will enable the interrupt signals from each
processor to be driven out to the jtag connector 109.
12-15, JTAG BREAK ENABLE FOR PROCESSOR 1 through 3.
Bit positions 12-15 when SET will enable each processor to be wire-ored
into the jtag break signal. This would only apply if the signal definition is
bidirectional open-collector.
16-30 - DEFINABLE
Bit positions 16-29 are users definable.
30 - JTAG BREAK ENABLE IN FROM ANOTHER MCC DEVICE.
Bit position 30 when SET will enable the JTAG BREAK signal in from
another MCC device.
31 - Bit position 31 when SET will clear the 32-bit status register.

TABLE 3
Status Register Format

0-3, HRESET OCCURED FROM PROCESSOR 1 through 4
Bit positions 0-3 when SET indicates that the hardware reset signal was
asserted at some point. This would be an unexpected reset indication.
4-7, TRST LOGIC LEVEL FROM PROCESSOR 1 through 4
Bit positions 4-7 when SET indicates the TRST signal's true (i.e., actual)
logic level.
8-11, DINT OCCURED FROM PROCESSOR 1 through 4
TO CONNECTOR
Bit positions 8-11 when SET indicates which processor caused
the interrupt.
12-15, JTAG BREAK OCCURED BY PROCESSOR 1 through 4
Bit positions 12-15 when SET indicates which processor caused the break.
16-19, HRESET LOGIC LEVEL FROM PROCESSOR 1 through 4
Bit positions 16-19 when SET indicates the HRESET signal's true
logic level.
20-30 - USERS DEFINABLE
Bit positions 20-30 are users definable.
30 - JTAG BREAK OCCURRED FROM ANOTHER MCC DEVICE.
Bit position 30 when SET indicates that cause of the break from another
MCC device.
31 - USER DEFINABLE.

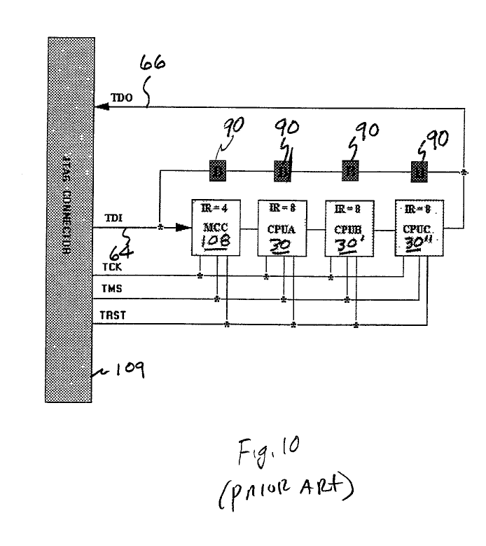

Turning now to FIG. 10, the IEEE 1149.1 compliance of embodiments of the present invention is discussed. FIG. 10 includes a simplified view of the scan chain 62′ of FIG. 7B, with non-JTAG communication pathways omitted for clarity. (Non-JTAG pathways are similarly omitted from FIG. 11, discussed below.) The bit length of Instruction Register 88 of each device is shown, which in this exemplary embodiment provides a total instruction register, pursuant to the IEEE 1149.1 specification, of 28 bits in length. The total number of devices in this embodiment is 4 (3 CPUs 30, 30′, 30″, and one MCC 108), so that the total number of TAP controllers 86 (see FIGS. 3&6) in the scan chain 62′ is also 4. If these 4 devices are physically separate, then this embodiment complies with the IEEE 1149.1 specification. However, in the event these devices are not physically separate, but rather are contained in a single integrated device, then achieving compliance with IEEE 1149.1 becomes problematic. Problems pertain to the use of multiple TAP controllers in a single device. As used herein, the term ‘integrated device’ and/or ‘single integrated device’ refers to a single chip, wafer, or chip-mounted microelectronic component pursuant to the IEEE 1149.1 specification.

For example, in the event all 4 devices were in BYPASS mode, the total number of bits between edge connector TDI 64 and edge connector TDO 66, would be 4. The IEEE 1149.1 specified BYPASS command dictates that any one physical device contain only one bit between its TDI 48 and TDO 50 (FIG. 3). So, the configuration of FIG. 10 implemented as four separate devices (each with a one-bit BYPASS register 90, shown separately from its device for clarity), would comply with the IEEE 1149.1 specification. However, this configuration, if integrated into a single device, would violate the IEEE 1149.1 specification due to use of more than one bit (i.e., four bits) in the total BYPASS register.

As shown in the embodiment of FIG. 11, one way to address this problem is to provide a shadow IR register 120 in combination with an additional BYPASS register 90′. The shadow IR register 120 is the same length as the total number of instruction register bits in chain 62′, and may be disposed within the MCC 108 as shown. In this example, register 120 is 28 bits long. As also shown, register 120 may be configured to copy and/or intercept data flow destined for the IR registers 88 of the devices in the scan chain (i.e., the shadow register may be selected upon receipt of BYPASS commands). When the shadow register becomes filled with all ones (the IEEE 1149.1 compliant BYPASS command format discussed hereinabove), then BYPASS register 90′ is selected, which effectively places all of the devices in BYPASS.

Effectively, during operation, the shadow register 120 is loaded with the contents of the total IR register. If all 28 bits are not ones, then the normal data flow will occur through the total IR (i.e., through the 28 bits of the individual IR registers 88). If all 28 bits are ones, then this serves as a BYPASS command for the entire integrated device. The 4 individual devices will contain BYPASS commands, and the MUX (multiplexer) 124′ will place (i.e., select) the single latch 90′ between TDI 64 and TDO 66. Thus, all 4 devices will enter BYPASS mode, but only one bit will be physically tied between external TDI 64 and TDO 66.

Similarly, an optional shadow IDCODE register 122 maybe provided for selection upon receipt of an IDCODE command. This IDCODE register 122 may be used to provide a single ID Code corresponding to the single integrated device, in conformance with the IEEE 1149.1 specification. In operation, the IDCODE command will place the 28 bit IDCODE register 122 between TDI 64 and TDO 66. The aforementioned 4 bit MCC instruction register IDCODE command of binary (0010) will select this register 122. The remaining 24 bits would typically be all ones (as shown in FIG. 11) so that the other TAP controllers 86 (of devices 30, 30′, and 30″) will execute BYPASS commands. Other nested commands may also be executed in a single scan. For example, to HALT all 3 processors 30, 30′, and 30″, the corresponding 3 groups of 8 bits (i.e., bits 4-27 in this example) may be processor halt commands, while the remaining 4 bits would select the IDCODE register.

Since, as mentioned hereinabove, the MCC device 108 is used to control all the non-JTAG signals used with the JTAG connector 109, the MCC 108 may also conveniently be used to store logic associated with the shadow register(s). Thus the MCC 108 and all associated logic, including shadow register logic and logic associated with JTAG communication, may advantageously be embodied within a single memory device, such as an FPGA.

Remaining JTAG commands, such as the SAMPLE_PRELOAD and EXTEST commands will function normally, as defined in the IEEE 1149.1 description. In particular, each component within a single chip will have it's own boundary scan definition file (BSDL) format. Single devices 30, 30′, 30″, etc., manipulated with these commands will react just as if they were single, external devices.

Although the MCC 108 has been shown and described herein as a hardware device, the skilled artisan will recognize that it may be implemented in software, e.g., as a ‘soft core’ device, without departing from the spirit and scope of the present invention.

In the preceding specification, the invention has been described with reference to specific exemplary embodiments thereof. It will be evident that various modifications and changes may be made thereunto without departing from the broader spirit and scope of the invention as set forth in the claims that follow. The specification and drawings are accordingly to be regarded in an illustrative rather than restrictive sense.

Having thus described the invention, what is claimed is:

1. A method, comprising:
placing a memory structure in a path of a JTAG scan chain in response to an instruction, the memory structure having multiple locations, at least portions of the memory structure being capable of storing first data and second data;
serially receiving at least one signal containing first data via the JTAG scan chain;
storing the first data in the memory structure;
receiving at least one other signal from at least one component on the JTAG scan chain;
transmitting the other signal to at least one other component on the scan chain;
placing second data into the memory structure; and
serially transmitting the second data via the JTAG scan chain.

2. The method of claim 1, wherein the component is selected from the group consisting of at least one of multiple devices on a JTAG scan chain, and an emulator.

3. The method of claim 1, wherein said second data comprises information responsive to the other signal.

4. The method of claim 3, wherein the other signal comprises a non-JTAG signal.

5. The method of claim 3, wherein said receiving comprises receiving the other signal from an emulator.

6. The method of claim 5, wherein:
the other signal comprises a reset signal, and is transmitted to a plurality of devices on the scan chain.

7. The method of claim 3, wherein said receiving comprises receiving the other signal from a device on the scan chain.

8. The method of claim 7, wherein the other signal comprises a reset signal.

9. The method of claim 7, wherein said transmitting comprises transmitting the other signal to a plurality of other devices on the scan chain.

10. The method of claim 7, wherein said receiving comprises receiving other signals from multiple devices on the JTAG scan chain.

11. The method of claim 10, wherein said receiving comprises receiving other signals from each of the multiple devices.

12. The method of claim 10, wherein said receiving is effected via parallel connections to each of the multiple devices.

13. The method of claim 1, wherein said placing a memory structure comprises serially receiving the instruction from an emulator coupled to the scan chain.

14. The method of claim 1, wherein said serially transmitting comprises transmitting the second data to an emulator coupled to the JTAG scan chain.

15. The method of claim 1, wherein said transmitting comprises transmitting the other signal to at least one device on the scan chain via at least one parallel connection.

16. The method of claim 15, wherein said transmitting comprises transmitting the other signal to each device on the scan chain via multiple parallel connections.

17. The method of claim 1, wherein the other signal comprises an interrupt signal.

18. The method of claim 1, further comprising:
placing second memory structures of multiple devices on the scan chain;
coupling a third memory structure to the scan chain in parallel with the second memory structures;
the third memory structure having at least as many locations as a combination of the second memory structures.

19. The method of claim 18, wherein the second memory structures comprise Instruction Registers.

20. The method of claim 18, wherein the second memory structures comprise Idcode registers.

21. The method of claim 18, further comprising coupling a Bypass register to the third memory structure.

22. The method of claim 21, comprising actuating the Bypass register upon receipt of a Bypass instruction in the third memory structure.

23. The method of claim 1, wherein the instruction comprises a JTAG compliant Controller Select instruction.

24. The method of claim 1, wherein the first data is selected from the group consisting of Reset Enable, Test Reset Enable, Interrupt Enable, JTAG Break Enable for Processor, JTAG Break Enable from another Controller, Clear, and combinations thereof.

25. The method of claim 1, wherein the second data is selected from the group consisting of Reset Occurred, Reset Logic Level, Interrupt Occurred, JTAG Break Occurred by Processor, JTAG Break Occurred from another Controller, and combinations thereof.

26. A controller for controlling multiple components, comprising:
an instruction memory structure;
a data memory structure;
control logic coupled to the instruction memory structure and the data memory structure;
signal logic coupled to the data memory structure;
a JTAG-compliant TAP controller coupled to the instruction memory structure;
a serial input port;
a serial output port;
at least one of said serial input port and said serial output port being selectively couplable to at least one of the instruction memory structure and the data memory structure;
a plurality of parallel inputs coupled to the signal logic and available to receive signals from each of the multiple components;
a plurality of parallel outputs coupled to the signal logic and available to transmit signals to each of the multiple components;
the control logic being configured to couple the data memory structure to the serial input port and serial output port upon implementation of an instruction in the instruction memory structure;
the signal logic being configured to receive and transmit signals between the multiple components upon receipt via the serial input port of first data in a first location of the data memory structure;
the signal logic being configured to place second data into a second location of the data memory structure in response to said first data; and
the data memory structure being configured to serially transmit the first and second data via the serial output port.

27. The controller of claim 26, wherein at least one of said serial input port and said serial output port are selectively couplable to at least one of an instruction register a bypass register, and an idcode register.

28. The controller of claim 26, wherein the multiple components include multiple devices and a JTAG connector coupled to the scan chain.

29. The controller of claim 28, wherein the multiple devices comprise three devices.

30. The controller of claim 26, wherein the devices are soft cores implemented in at least one computer readable medium.

31. The controller of claim 30, wherein the devices are implemented in an FPGA.

32. The controller of claim 26, being implemented in a computer readable medium, and wherein the devices are soft cores disposed in said computer readable medium.

33. The controller of claim 32, wherein said computer readable medium comprises an FPGA.

34. The controller of claim 32, being configured to enable the soft cores to be loaded into said computer readable medium via the scan chain.

35. The controller of claim 26, configured for being responsive to JTAG and non-JTAG signals.

36. The controller of claim 26, wherein the components are selected from the group consisting of at least one of multiple devices on a JTAG scan chain, and an emulator.

37. The controller of claim 26, wherein said second data comprises information responsive to the other signal.

38. The controller of claim 37, wherein the signals comprises non-JTAG signals.

39. The controller of claim 37, wherein the signal logic is configured to receive a signal from an emulator.

40. The controller of claim 39, wherein:
the signal comprises a reset signal, and the signal logic is configured to transmit the reset signal to a plurality of devices on the scan chain.

41. The controller of claim 26, wherein a signal is received from a device on the scan chain.

42. The controller of claim 41, wherein the signal comprises a reset signal.

43. The controller of claim 41, wherein the signal is transmitted to a plurality of other devices on the scan chain.

44. The controller of claim 41, wherein other signals are received from multiple devices on the JTAG scan chain.

45. The controller of claim 44, wherein other signals are received from each of the multiple devices.

46. The controller of claim 26, being configured to serially receive the instruction from an emulator coupled to the scan chain.

47. The controller of claim 26, being configured to transmit the second data to an emulator coupled to the JTAG scan chain.

48. The controller of claim 26, being configured to transmit a signal to at least one device on the scan chain via at least one parallel connection.

49. The controller of claim 48, being configured to transmit a signal to each device on the scan chain via multiple parallel connections.

50. The controller of claim 26, wherein the signal comprises an interrupt signal.

51. The controller of claim 26, further comprising:
a second memory structure configured for being disposed on the scan chain in series with second memory structures of devices in the scan chain;
a third memory structure configured for being coupled to the scan chain in parallel with each of the second memory structures;
the third memory structure having at least as many locations as a combination of each of the second memory structures.

52. The controller of claim 51, wherein the second memory structures comprise Instruction Registers.

53. The controller of claim 51, wherein the second memory structures comprise Idcode registers.

54. The controller of claim 51, further comprising a Bypass register coupled to the third memory structure.

55. The controller of claim 54, wherein the Bypass register is actuatable upon receipt of a Bypass instruction in the third memory structure.

56. The controller of claim 26, wherein the instruction comprises a JTAG compliant Controller Select instruction.

57. The controller of claim 26, wherein the first data is selected from the group consisting of Reset Enable, Test Reset Enable, Interrupt Enable, JTAG Break Enable for Processor, JTAG Break Enable from another Controller, Clear, and combinations thereof.

58. The method of claim 26, wherein the second data is selected from the group consisting of Reset Occurred, Reset Logic Level, Interrupt Occurred, JTAG Break Occurred by Processor, JTAG Break Occurred from another Controller, and combinations thereof.

59. A method comprising:
transmitting a first instruction to place multiple instruction memory structures on a JTAG scan chain;
serially transmitting a second instruction via the JTAG scan chain, the second instruction to place a controller data memory structure on the JTAG scan chain;
serially transmitting at least one signal containing first controller data via the JTAG scan chain;
transmitting at least one other signal to a component on the JTAG scan chain; and
serially receiving second controller data corresponding to multiple devices from the data memory structure via the JTAG scan chain.

60. The method of claim 59, further comprising re-transmitting the first instruction after said serially receiving.

61. The method of claim 59, wherein said second controller data comprises information responsive to the other signal.

62. The method of claim 61, wherein the other signal comprises a non-JTAG signal.

63. The method of claim 61, wherein the other signal comprises a reset signal, and is transmitted to a plurality of devices on the scan chain.

64. The method of claim 59, wherein said second data indicates the other signal was transmitted to multiple devices on the JTAG scan chain.

65. The method of claim 59, wherein the other signal comprises an interrupt signal.

66. An emulator for debugging multiple devices on a JTAG scan chain, comprising:
a processor;
a scan chain signal handler configured to transmit and receive signals via the scan chain;
a TAP controller signal handler configured to send and receive instructions via parallel connections to each TAP controller on the scan chain; and
a non-JTAG signal handler configured to transfer non-JTAG signals to and from a controller disposed on the scan chain.

67. The emulator of claim 66, wherein:
said scan chain signal handler is configured to transmit a first instruction to place multiple instruction memory structures on a JTAG scan chain;
said TAP controller signal handler is configured to serially transmit a second instruction via the JTAG scan chain to place a controller data memory structure on the JTAG scan chain;
said scan chain signal handler being further configured to serially transmit at least one signal containing first controller data via the JTAG scan chain;
said non-JTAG signal handler being configured to transmit at least one other signal to at least one device on the JTAG scan chain; and
said scan chain signal handler being configured to serially receive second controller data corresponding to multiple devices from the data memory structure via the JTAG scan chain.

68. The emulator of claim 66, comprising:
a JTAG connector configured for coupling the emulator to the scan chain.

69. The emulator of claim 68, further comprising:
a controller coupled to said JTAG connector.

70. The emulator of claim 69, wherein said controller comprises:
a data memory structure;
control logic coupled to the instruction memory structure and the data memory structure;
signal logic coupled to the data memory structure;
a JTAG-compliant TAP controller coupled to the instruction memory structure;
a serial input port;
a serial output port;
at least one of said serial input port and said serial output port being selectively couplable to one of the instruction memory structure and the data memory structure;
a plurality of parallel inputs coupled to the signal logic and available to receive signals from each of the multiple components;
a plurality of parallel outputs coupled to the signal logic and available to transmit signals to each of the multiple components;
the control logic being configured to couple the data memory structure to the serial input port and serial output port upon implementation of an instruction in the instruction memory structure;
the signal logic being configured to receive and transmit signals between the multiple components upon receipt via the serial input port of first data in a first location of the data memory structure;
the signal logic being configured to place second data into a second location of the data memory structure in response to said first data; and
the data memory structure being configured to serially transmit the first and second data via the serial output port.

71. The emulator of claim 69, comprising:
a plurality of devices coupled to said controller in the scan chain.

72. The emulator of claim 71, wherein said controller and said devices comprise program code disposed on a computer readable medium.

73. The emulator of claim 72, wherein said computer readable medium comprises an FPGA.

74. A method, comprising:
with an emulator, transmitting a first instruction to place multiple instruction memory structures on a JTAG scan chain, the scan chain including a plurality of devices and a controller;
with the emulator, serially transmitting a second instruction via the JTAG scan chain;
placing a memory structure of the controller in a path of the JTAG scan chain in response to the second instruction, the memory structure having multiple locations, at least portions of the memory structure being capable of storing first data and second data;
with the emulator, serially transmitting at least one signal containing first controller data via the JTAG scan chain;
serially receiving the one signal with the controller;
storing the first data in the memory structure;
transmitting at least one other signal from the emulator;
receiving the other signal with the controller;
transmitting the other signal from the controller to the plurality of devices;
using the controller to place second data into the memory structure;
serially transmitting the second data corresponding to the devices via the JTAG scan chain; and
serially receiving the second data with the emulator via the JTAG scan chain.

75. A system comprising:
a JTAG scan chain including multiple devices;
an emulator for debugging the multiple devices, including:
a processor;
a scan chain signal handler coupled to the scan chain to transmit and receive signals;
a TAP controller signal handler configured to send and receive instructions via parallel connections to each TAP controller on the scan chain; and
a non-JTAG signal handler configured to transfer non-JTAG signals to and from a controller disposed on the scan chain; and a controller, including:
an instruction memory structure;
a data memory structure;
control logic coupled to the instruction memory structure and the data memory structure;
signal logic coupled to the data memory structure;
a JTAG-compliant TAP controller coupled to the instruction memory structure;
a serial input port coupled to the scan chain signal handler;
a serial output port coupled to the scan chain;
at least one of said serial input port and said serial output port being selectively couplable to one of the instruction memory structure and the data memory structure;
a plurality of parallel inputs coupled to the signal logic and to each of the multiple components and to the non-JTAG signal handler;
a plurality of parallel outputs coupled to the signal logic and to each of the multiple components and to the non-JTAG signal handler;
the control logic being configured to couple the data memory structure to the serial input port and serial output port upon implementation of an instruction in the instruction memory structure received from the emulator;
the signal logic being configured to receive and transmit signals between the multiple components upon receipt via the serial input port of first data in a first location of the data memory structure;
the signal logic being configured to place second data into a second location of the data memory structure in response to said first data; and
the data memory structure being configured to serially transmit the first and second data via the serial output port to the emulator.
